(19) United States
(12) Patent Application Publication
(10) Pub. No.: US 2008/0159361 A1
(43) Pub. Date: Jul. 3, 2008

(54) Dynamically adjusted phase locked loop

(75) Inventors: Juha Hallivuori, Tampere (FI); Sami L. Rintamaki, Helsinki (FI)

Correspondence Address: HARRINGTON & SMITH, PC, 4 RESEARCH DRIVE, SHELTON, CT, 06484-6212, US

(73) Assignee: Nokia Corporation

(21) Appl. No.: 12/005,215

(22) Filed: Dec. 26, 2007

(30) Foreign Application Priority Data
Dec. 29, 2006 (GB) 06260024.4

(51) Int. Cl. H03K 11/00

(52) U.S. Cl. 375/215

(57) ABSTRACT

The present invention relates to a dynamically adjusted phase-locked loop (PLL). The level of capacitance of the loop filter and the level of current of the charge pump of the phase-locked loop are adjusted in accordance with an analogue method.

### FIELD OF THE INVENTION

The present invention is related to a dynamically adjusted phase locked loop, and more particularly, a phase locked loop with a loop filter with a variable capacitance.

### BACKGROUND

A phase-locked loop (PLL) converges the frequency and phase of an output signal towards a reference input signal. When the output signal matches the input signal the PLL locks.

A PLL includes a phase detector (PD) which compares the input signal to the output signal (or to a frequency divided version of the output signal). The PD generates an error signal representing the difference between phases of the two signals. A charge pump receives the error signal which determines the amount of charge that is to be provided to a loop filter. The charge provided by the charge pump loads the capacitors of the loop filter. The voltage output of the loop filter increases or decreases the speed (frequency) of a voltage controlled oscillator (VCO). The VCO produces an output signal. The output signal of the VCO is feed back into the phase detector. The output signal may be frequency divided before being fed back into the phase detector.

At times, the frequency of the output signal is needed to be changed (for example, in a radio transceiver where signals are transmitted at different frequencies according to a hopping pattern). The maximum time that is allowed for the output signal to change from one frequency to another frequency is usually defined in the used radio standard.

Optimum loop performance is usually different for normal operation, when the frequency is constant and for frequency change, when the output signal should converge quickly.

To vary the speed at which the output signal converges, the loop filter may be switched to enable additional/lesser capacitors to be charged to provide a slower/faster control voltage change for the VCO and thus to enable the oscillation frequency of the output signal to be varied slower or faster. The charge pump maximum current level can also be altered to achieve desired loop performance. The amount of charge per given error signal can be adjusted by the maximum current level.

The disadvantage with using a switched loop filter is that when the capacitors in the loop filter are switched on and off spikes can be produced in the voltage and this can cause the PLL to lose lock or produce defects in the generated frequency.

Some PLL can be controlled by an external microprocessor or microcontroller which transmits control signals to the PLL. However such systems are problematic in that processor cycles and processor power is required to be used to monitor and control the PLL. This increases the complexity of the system and increased power consumption has a negative effect on battery consumption for mobile devices using PLL systems.

There is a desire for an improved alternative.

It is an object of the present invention to provide a phase-locked loop which overcomes the disadvantages of the prior art, or at least provides a useful alternative.

### SUMMARY

According to an embodiment there is provided a phase-locked loop, comprising: a phase or phase/frequency detector configured to detect the phase or phase/frequency difference between a reference signal and an output signal originating from a voltage/current controlled oscillator, and to produce a first control signal corresponding to the difference; a dynamic controller configured to set an analogue level of a variable signal provided by a charge pump and an analogue level of variable capacitance of a loop filter; a charge pump configured to provide a variable signal to a loop filter based at least in part on the first control signal; a loop filter, comprising at least one variable capacitance, configured to filter the variable signal from the charge pump so to provide a second control signal for a voltage/current controlled oscillator; and a voltage/current controlled oscillator configured for producing an output signal in dependence on the second control signal.

Embodiments of the invention may offer a possibility of dynamically configurable phase-locked loop. Embodiments incorporated into devices may have better battery life and be require less powerful processors to operate the remaining functions of the device.

The dynamic controller may be configured to set the level of a variable signal provided by a charge pump and the level of variable capacitance of a loop filter based at least in part on the first control signal.

The at least one variable capacitance may comprise one or more miller capacitors.

The voltage/current controlled oscillator may comprise a voltage controlled oscillator.

According to another embodiment there is provided a method of tuning a loop filter of a phase locked loop comprising: detecting the phase or phase/frequency difference between a reference signal and an output signal originating from a voltage/current controlled oscillator, producing a first control signal corresponding to the phase/frequency difference; setting an analogue level of a variable signal provided by a charge pump and an analogue level of variable capacitance of a loop filter; providing a variable signal to a loop filter based at least in part on the first control signal; filtering the variable signal so to provide a second control signal; and producing an output signal in dependence on the second control signal.

Setting the level of the variable signal and the level of variable capacitance is preferably based at least in part on the first control signal.

The at least one variable capacitance may comprise one or more miller capacitors.

According to a further embodiment there is provided a method of tuning a loop filter of a phase locked loop, comprising: automatically modifying an analogue level of maximum current provided by a charge pump; automatically modifying an analogue level of at least one variable capacitance of a loop filter; the charge pump providing a charge pump signal to the loop filter; and the loop filter filtering the charge pump signal to produce a control signal for a voltage/current controlled oscillator.

The method may comprise detecting the phase difference between a reference signal and an output signal originating from the voltage/current controlled oscillator, and producing a control signal corresponding to the difference.

The current level provided by the charge pump and the level of capacitance of the loop filter are preferably automatically modified based at least in part on the control signal.

The variable capacitance of the loop filter is preferably provided by one or more miller capacitors.

The voltage/current controlled oscillator preferably comprises a voltage controlled oscillator.

According to a yet further embodiment there is provided a phase-locked loop, comprising: means for detecting the phase or phase/frequency difference between a reference signal and an output signal originating from a voltage/current controlled oscillator; means for producing a first control signal corresponding to the difference; means for setting an analogue level of a variable signal and an analogue level of variable capacitance of a loop filter; means for providing a variable signal based at least in part on the first control signal; means for filtering the variable signal so to provide a second control signal; and means for producing an output signal in dependence on the second control signal.

The phase-locked loop as described above may be incorporated into one of a mixer, a transmitter, a receiver, a user equipment, and a base station.

### BRIEF DESCRIPTION OF THE DRAWINGS

Embodiments of the invention will now be described, by way of example only, with reference to the accompanying drawings in which:

FIG. 1 shows a schematic diagram illustrating a phase-locked loop;

FIG. 2 shows a schematic diagram illustrating a phase-locked loop in accordance with an embodiment of the invention; and

FIGS. 3 and 4 show flowcharts in accordance with certain embodiments.

### DETAILED DESCRIPTION OF CERTAIN EMBODIMENTS

The present invention provides phase-locked loop (PLL) which is dynamically adjusted. The capacitance of the loop filter and the current of the charge pump of the phase-locked loop are adjusted in accordance with an analogue method rather than a discrete method.

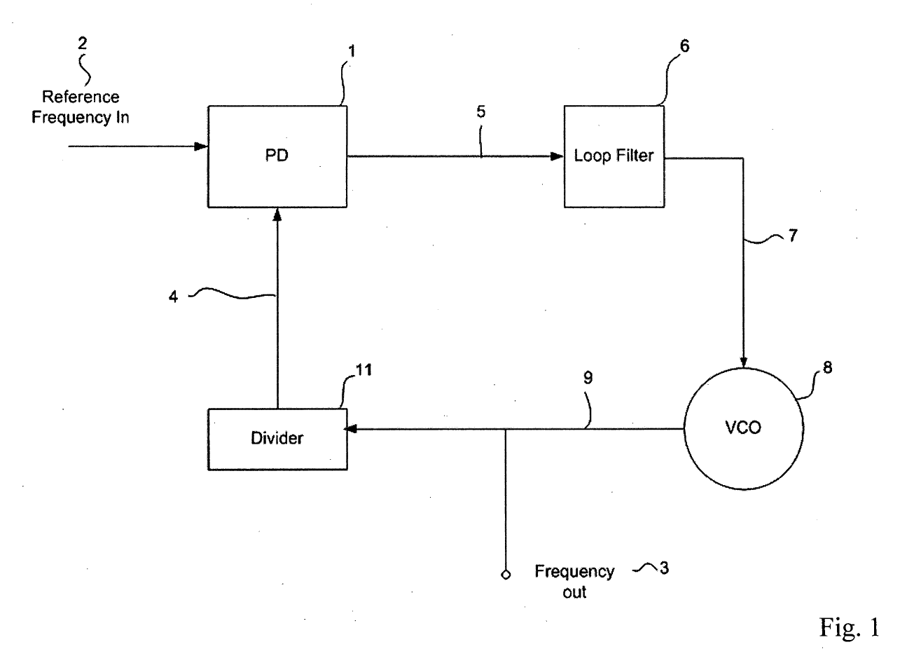

FIG. 1 shows a phase-locked loop (PLL).

The PLL includes a phase detector (PD) 1 which compares a reference signal 2 to the frequency output signal 3 (or to a frequency divided version of the output signal 4).

The PD 1 generates an error signal representing the difference between phases of the two signals. A charge pump receives the error signal which determines the amount of charge 5 that is to be provided to a loop filter 6. In this example, the charge pump is integrated with the PD 1 and is not shown.

The charge 5 provided by the charge pump loads the capacitors of the loop filter 6.

The voltage output 7 of the loop filter 6 increases or decreases the frequency of a voltage controlled oscillator (VCO) 8. The VCO 8 produces an output signal 9 based on its frequency.

The output signal 9 of the VCO 8 is feed back 10 into the phase detector 1. The output signal may be frequency divided by a divider 11 before being fed back 4 into the phase detector.

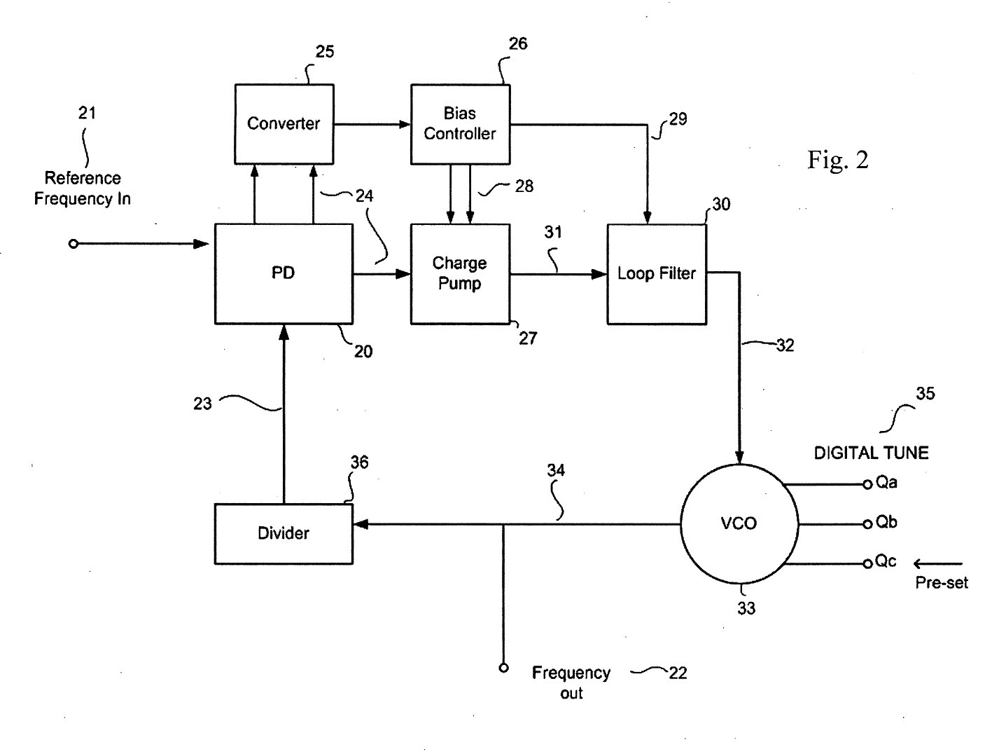

FIG. 2 shows a dynamically adjusted phase-locked loop in accordance with an embodiment of the invention.

The PLL includes a phase detector (PD) 20 which compares a reference signal 21 to the frequency output signal 22 (or to a frequency divided version of the output signal 23).

The PD generates a control signal 24 representing the difference between phases of the two signals.

The control signal 24 is passed to a converter 25 which voltage converts the control signal for a bias controller 26.

The control signal 24 is also passed to a charge pump 27.

The bias controller 26 produces a charge pump bias signal 28 to control the bias across the charge pump 27. For example, the signal may set the bias of a current source in a charge pump 27.

The bias also produces a loop filter bias signal 29 to control the bias across a loop filter 30. For example, the signal may set the amplification bias of one or more miller capacitors within the loop filter. The amplification level of the miller capacitors determines the capacitance level of the loop filter.

It will be appreciated that the capacitance of the loop filter may be active or passive.

The charge pump 27 produces a charge 31 based on the control signal 24 from the phase detector with certain adjusted current setting.

The charge 31 loads the capacitance of the loop filter 30.

When the loop filter 30 discharges its load, a voltage 32 is produced. This voltage signal 32 is provided to a voltage controlled oscillator (VCO) 33. The voltage controls the oscillation of the VCO 33 so that the VCO 33 produces a frequency output signal 22 and 34.

The VCO may also be digitally tunable 35.

The frequency output signal 22 may then be output and used by other components (not shown). For example, the frequency output signal may be used by a cellular transmitter.

The frequency output signal 34 is also provided to the phase detector to complete the loop. The frequency output signal 23 may be first divided by a divider 36.

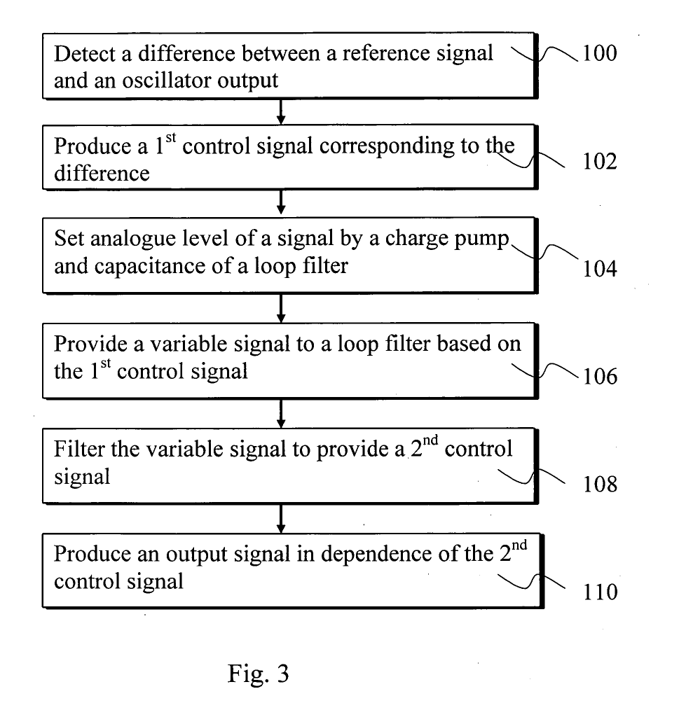

FIG. 3 shows a flowchart in accordance with an embodiment for tuning a loop filter of a phase locked loop. In the method the phase or phase/frequency difference between a reference signal and an output signal originating from a voltage/current controlled oscillator is detected at 100. A first control signal corresponding to the phase/frequency difference may then be produced at 102. Setting of an analogue level of a variable signal provided by a charge pump and an analogue level of variable capacitance of a loop filter may then follow at 104. A variable signal is provided at 106 to a loop filter based at least in part on the first control signal. At 108 the variable signal is filtered so to provide a second control signal. An output signal can then be produced at 110. The output signal is produced in dependence on the second control signal.

In accordance with a possibility the setting of the level of the variable signal and the level of variable capacitance at 104 is based at least in part on the first control signal.

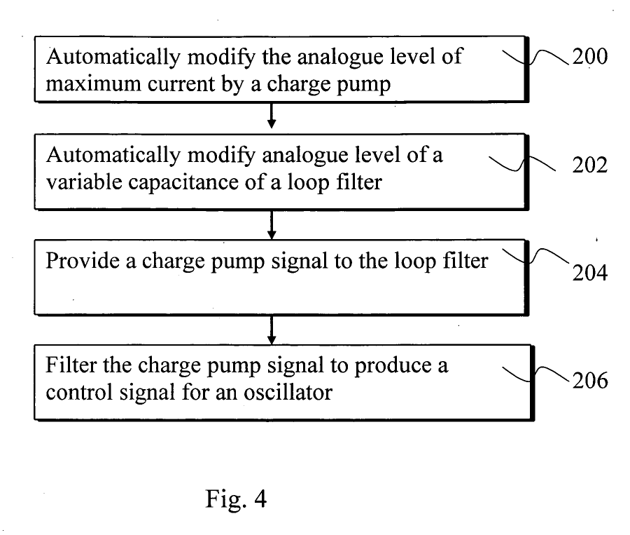

FIG. 4 is a flowchart in accordance with another method for tuning a loop filter of a phase locked loop. In this method an analogue level of maximum current provided by a charge pump is automatically modified at 200. An analogue level of at least one variable capacitance of a loop filter is automatically modified at 202. The charge pump provides a charge pump signal to the loop filter at 204. The loop filter can then filter the charge pump signal at 206 to produce a control signal for a voltage/current controlled oscillator.

The method of FIG. 4 may comprise a step of detecting the phase difference between a reference signal and an output signal originating from the voltage/current controlled oscillator. A control signal corresponding to the difference may then be produced. The current level provided by the charge pump and the level of capacitance of the loop filter may be automatically modified based at least in part on the control signal.

As can be seen, in one embodiment, the charge produced by the charge pump and the capacitance of the loop filter is proportional to the difference in phase of the frequencies. Therefore, the voltage produced by the loop filter will increase when the difference in phase is great. The consequence of this is that the VCO will change the output frequency signal faster when the phase difference is larger (loose loops). In addition, as the difference in phase decreases (tight loops) the voltage produced by the loop filter is lower and the VCO will change the output frequency signal slower. This ensures that the ability of the PLL to converge is not impaired.

It will be appreciated that, with appropriate modifications, a current controlled oscillator may be used in place of the voltage controller oscillator.

In an alternative embodiment of the invention, the capacitance size of the loop filter and/or the charge quantity of the charge pump is determined by a control signal from another portion of the PLL.

Embodiments of the present invention provide the advantage that capacitance is increased/decreased within the loop filter in a continuous analogue fashion and with reference to the actual frequency state. This results in smooth transitions between tight loop and loose loop cases in PLL operation. This smooth transition will reduce defects in the generated frequency spectrum.

It is noted that embodiments of the present invention may be implemented into transmitters or receivers where a phase-locked loop is used as an input to a mixer for up or down converting one signal frequency to a second frequency.

Furthermore embodiments of the present invention may be implemented into user equipment, base station transmitters and receivers where accurate and/or tuneable oscillators are required.

It is noted that embodiments of the present invention may be implemented into mobile user devices. Furthermore embodiments of the present invention are applicable to any other suitable type of apparatus suitable for communication via access systems. A mobile device may be configured to enable use of different access technologies, for example, based on an appropriate multi-radio implementation.

It is also noted that embodiments described above may be implemented into mobile devices which may communicate with reference to architectures of certain mobile networks and wireless local area networks. Further embodiments of the invention may be implemented in mobile devices applied to any suitable form of communication systems. It is also noted that the term access system is understood to refer to any access system configured for enabling wireless communication for user accessing applications.

While the present invention has been illustrated by the description of the embodiments thereof, and while the embodiments have been described in considerable detail, it is not the intention of the applicant to restrict or in any way limit the scope of the appended claims to such detail. Additional advantages and modifications will readily appear to those skilled in the art. Therefore, the invention in its broader aspects is not limited to the specific details representative apparatus and method, and illustrative examples shown and described. Accordingly, departures may be made from such details without departure from the spirit or scope of applicant's general inventive concept.

1. A phase-locked loop, comprising:
a phase or phase/frequency detector configured to detect the phase or phase/frequency difference between a reference signal and an output signal originating from a voltage/current controlled oscillator, and to produce a first control signal corresponding to the difference;
a dynamic controller configured to set an analogue level of a variable signal provided by a charge pump and an analogue level of variable capacitance of a loop filter;
a charge pump configured to provide a variable signal to a loop filter based at least in part on the first control signal;
a loop filter, comprising at least one variable capacitance, configured to filter the variable signal from the charge pump so to provide a second control signal for a voltage/current controlled oscillator; and
a voltage/current controlled oscillator configured for producing an output signal in dependence on the second control signal.

2. The phase-locked loop as claimed in claim 1, wherein the dynamic controller is configured to set the level of a variable signal provided by a charge pump and the level of variable capacitance of a loop filter based at least in part on the first control signal.

3. The phase-locked loop as claimed in claim 1, wherein the at least one variable capacitance comprises one or more miller capacitors.

4. The phase-locked loop as claimed in claim 1, wherein the voltage/current controlled oscillator comprises a voltage controlled oscillator.

5. A method of tuning a loop filter of a phase locked loop comprising:
detecting the phase or phase/frequency difference between a reference signal and an output signal originating from a voltage/current controlled oscillator,
producing a first control signal corresponding to the phase/frequency difference;
setting an analogue level of a variable signal provided by a charge pump and an analogue level of variable capacitance of a loop filter;
providing a variable signal to a loop filter based at least in part on the first control signal;
filtering the variable signal so to provide a second control signal; and
producing an output signal in dependence on the second control signal.

6. The method as claimed in claim 5, wherein setting the level of the variable signal and the level of variable capacitance is based at least in part on the first control signal.

7. The method as claimed in claim 5, wherein the at least one variable capacitance comprises one or more miller capacitors.

8. A method of tuning a loop filter of a phase locked loop, comprising
automatically modifying an analogue level of maximum current provided by a charge pump;
automatically modifying an analogue level of at least one variable capacitance of a loop filter;
the charge pump providing a charge pump signal to the loop filter; and
the loop filter filtering the charge pump signal to produce a control signal for a voltage/current controlled oscillator.

9. The method as claimed in claim 8 comprising detecting the phase difference between a reference signal and an output signal originating from
the voltage/current controlled oscillator, and
producing a control signal corresponding to the difference.

10. The method as claimed in claim 9 wherein the current level provided by the charge pump and the level of capacitance of the loop filter are automatically modified based at least in part on the control signal.

11. The method as claimed in claim 8, wherein the variable capacitance of the loop filter is provided by one or more miller capacitors.

12. The method as claimed in any claim 8, wherein the voltage/current controlled oscillator comprises a voltage controlled oscillator.

13. A phase-locked loop, comprising:
means for detecting the phase or phase/frequency difference between a reference signal and an output signal originating from a voltage/current controlled oscillator,
means for producing a first control signal corresponding to the difference;
means for setting an analogue level of a variable signal and an analogue level of variable capacitance of a loop filter;
means for providing a variable signal based at least in part on the first control signal;
means for filtering the variable signal so to provide a second control signal; and
means for producing an output signal in dependence on the second control signal.

14. A mixer comprising a phase-locked loop comprising:
a phase or phase/frequency detector configured to detect the phase or phase/frequency difference between a reference signal and an output signal originating from a voltage/current controlled oscillator, and to produce a first control signal corresponding to the difference;
a dynamic controller configured to set an analogue level of a variable signal provided by a charge pump and an analogue level of variable capacitance of a loop filter;
a charge pump configured to provide a variable signal to a loop filter based at least in part on the first control signal;
a loop filter, comprising at least one variable capacitance, configured to filter the variable signal from the charge pump so to provide a second control signal for a voltage/current controlled oscillator; and
a voltage/current controlled oscillator configured for producing an output signal in dependence on the second control signal.

15. A transmitter comprising a phase locked loop comprising:
a phase or phase/frequency detector configured to detect the phase or phase/frequency difference between a reference signal and an output signal originating from a voltage/current controlled oscillator, and to produce a first control signal corresponding to the difference;
a dynamic controller configured to set an analogue level of a variable signal provided by a charge pump and an analogue level of variable capacitance of a loop filter;
a charge pump configured to provide a variable signal to a loop filter based at least in part on the first control signal;
a loop filter, comprising at least one variable capacitance, configured to filter the variable signal from the charge pump so to provide a second control signal for a voltage/current controlled oscillator; and
a voltage/current controlled oscillator configured for producing an output signal in dependence on the second control signal.

16. A receiver comprising a phase locked comprising:
a phase or phase/frequency detector configured to detect the phase or phase/frequency difference between a reference signal and an output signal originating from a voltage/current controlled oscillator, and to produce a first control signal corresponding to the difference;
a dynamic controller configured to set an analogue level of a variable signal provided by a charge pump and an analogue level of variable capacitance of a loop filter;
a charge pump configured to provide a variable signal to a loop filter based at least in part on the first control signal;
a loop filter, comprising at least one variable capacitance, configured to filter the variable signal from the charge pump so to provide a second control signal for a voltage/current controlled oscillator; and
a voltage/current controlled oscillator configured for producing an output signal in dependence on the second control signal.

17. A user equipment comprising a phase-locked loop comprising:
a phase or phase/frequency detector configured to detect the phase or phase/frequency difference between a reference signal and an output signal originating from a voltage/current controlled oscillator, and to produce a first control signal corresponding to the difference;
a dynamic controller configured to set an analogue level of a variable signal provided by a charge pump and an analogue level of variable capacitance of a loop filter;
a charge pump configured to provide a variable signal to a loop filter based at least in part on the first control signal;
a loop filter, comprising at least one variable capacitance, configured to filter the variable signal from the charge pump so to provide a second control signal for a voltage/current controlled oscillator; and
a voltage/current controlled oscillator configured for producing an output signal in dependence on the second control signal.

18. A base station comprising a phase-locked loop comprising:
a phase or phase/frequency detector configured to detect the phase or phase/frequency difference between a reference signal and an output signal originating from a voltage/current controlled oscillator, and to produce a first control signal corresponding to the difference;
a dynamic controller configured to set an analogue level of a variable signal provided by a charge pump and an analogue level of variable capacitance of a loop filter;
a charge pump configured to provide a variable signal to a loop filter based at least in part on the first control signal;
a loop filter, comprising at least one variable capacitance, configured to filter the variable signal from the charge pump so to provide a second control signal for a voltage/current controlled oscillator; and
a voltage/current controlled oscillator configured for producing an output signal in dependence on the second control signal.
